(19) United States
(12) Patent Application Publication
(10) Pub. No.: US 2025/0022707 A1
(43) Pub. Date: Jan. 16, 2025

(54) COMPOSITE SUBSTRATE INCLUDING A TRANSFER FOIL WITH POROUS SILICON CARBIDE LAYER, POWER SEMICONDUCTOR DEVICE AND METHOD OF MANUFACTURING

(71) Applicant: Infineon Technologies AG, Neubiberg (DE)

(72) Inventor: Matteo Piccin, Villach (AT)

(21) Appl. No.: 18/768,095

(22) Filed: Jul. 10, 2024

(30) Foreign Application Priority Data
Jul. 14, 2023 (DE) 102023118720.1

(51) Int. Cl. H01L 21/02; H01L 29/16; H01L 29/78; H01L 29/861

(52) U.S. Cl. CPC H01L 21/02529; H01L 29/1608; H01L 29/7802; H01L 29/861

(57) ABSTRACT

A method of manufacturing a silicon carbide device includes forming a transfer foil that includes a porous silicon carbide layer. A composite substrate is formed that includes the transfer foil and a support substrate. The transfer foil and the support substrate are brought into contact with each other and connected to each other. An epitaxial layer is formed on a side of the porous silicon carbide layer opposite to the support substrate. The composite substrate is divided into a device substrate and a reclaim substrate. The device substrate includes the epitaxial layer and the reclaim substrate includes the support substrate.

### TECHNICAL FIELD

Examples of the present disclosure relate to a composite substrate that includes a transfer foil with a porous silicon carbide layer, a power semiconductor device, and a method of manufacturing a power semiconductor device. The method uses a transfer foil to transfer a porous silicon carbide layer to a support substrate. The composite substrate includes a transfer foil and a support substrate. The power semiconductor device may be obtained from the composite substrate.

### BACKGROUND

Fabrication of semiconductor wafers typically includes forming crystal ingots by vertical zone melting or by pulling a seed crystal rod from a crucible filled with molten semiconductor material and slicing the crystal ingots. Typical slicing processes destroy significant parts of the previously generated crystal. An alternative technique obtains epitaxial semiconductor wafers by forming a thin release layer near a front side of a re-usable semiconductor seed wafer, epitaxially growing a semiconductor layer on the front side and then mechanically detaching the epitaxially grown semiconductor layer from the seed wafer by means of the release layer. For example, an epitaxially grown semiconductor wafer is cleaved off from a single crystalline base substrate along a release layer formed by laser radiation. There is a steady need for methods that provide semiconductor wafers in an economic way.

### SUMMARY

An embodiment of the present disclosure relates to a method of manufacturing a silicon carbide device. The method includes forming a transfer foil including a porous silicon carbide layer. A composite substrate is formed that includes the transfer foil and a support substrate, wherein the transfer foil and the support substrate are brought into contact with each other and connected to each other. An epitaxial layer is formed on a side of the porous silicon carbide layer opposite to the support substrate. The composite substrate is divided into a device substrate and a reclaim substrate, the device substrate including the epitaxial layer and the reclaim substrate including the support substrate.

The method decouples a process of providing a suitable epitaxy seed from the actual epitaxy process and simplifies the fabrication of thin silicon carbide substrates for power semiconductor devices. A high-quality source substrate provides the epitaxy seed and a low-cost support substrate can be used for the epitaxy process. The porous silicon carbide layer first transfers the epitaxy seed to the low-cost support substrate and then enables efficient separation of a device substrate with electronic elements formed therein from the low-cost support substrate.

Those skilled in the art will recognize additional features and advantages upon reading the following detailed description and on viewing the accompanying drawings.

### BRIEF DESCRIPTION OF THE DRAWINGS

The accompanying drawings serve to further understand the embodiments and are an integral part of the description. The drawings illustrate embodiments of a power semiconductor device, a composite substrate and a method of manufacturing a semiconductor device and, together with the description, serve to explain the embodiments. The following detailed description and the claims contain further embodiments.

FIG. 1A to FIG. 1D show schematic vertical cross-sectional views of a transfer foil, a composite substrate, a device substrate and a reclaim substrate at various stages of a semiconductor device manufacturing method that includes transferring and horizontally splitting a porous silicon carbide layer according to an embodiment.

FIG. 2A to FIG. 2D show schematic vertical cross-sectional views of a transfer foil, a composite substrate, a device substrate and a reclaim substrate at various stages of a semiconductor device manufacturing method including transferring and horizontally splitting a porous silicon carbide layer according to an embodiment concerning a transfer foil including an auxiliary layer.

FIG. 3A to FIG. 3D show schematic vertical cross-sectional views of a composite substrate and a device substrate at various stages of a semiconductor device manufacturing method including transferring and horizontally splitting a porous silicon carbide layer according to an embodiment concerning formation of electronic elements before splitting the porous silicon carbide layer.

FIG. 4A to FIG. 4C show schematic vertical cross-sectional views of a source substrate and a transfer foil at various stages of a semiconductor device manufacturing method including transferring and horizontally splitting a porous silicon carbide layer according to an embodiment including formation of a porous silicon carbide layer for a transfer foil on a source substrate.

FIG. 5 is a schematic vertical cross-sectional view of a composite substrate including a porous silicon carbide layer and a silicon carbide recycle substrate according to an embodiment with the porous silicon carbide layer bonded directly on the silicon carbide recycle substrate.

FIG. 6 is a schematic vertical cross-sectional view of a composite substrate including a porous silicon carbide layer and a silicon carbide recycle substrate according to an embodiment with an interface layer formed between the porous silicon carbide layer and the silicon carbide recycle substrate.

FIG. 7 is a schematic vertical cross-sectional view of a silicon carbide power diode with a laterally homogenously doped porous silicon carbide portion.

FIG. 8 is a schematic vertical cross-sectional view of a silicon carbide power transistor with a laterally homogenously doped porous silicon carbide portion.

### DETAILED DESCRIPTION

In the following detailed description, reference is made to the accompanying drawings, which form a part hereof and in which are shown by way of illustrations specific embodiments in which a composite wafer, a power semiconductor device and a method of manufacturing a semiconductor device may be practiced. Other embodiments may be utilized, and structural or logical changes may be made without departing from the concept of the present disclosure. Features illustrated or described for one embodiment can be used on or in conjunction with other embodiments to yield yet a further embodiment. It is intended that the present disclosure includes such modifications and variations. The examples are described in a way, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The term “directly electrically connected” describes a permanent low-resistive ohmic connection between the directly electrically connected elements, e.g., a direct contact between the elements concerned or a low-resistance connection via a metal and/or heavily doped semiconductor material. The terms “electrically connected” and “signal connected” include the direct electrical connection and additionally allow for further electrical elements in a signal path or power supply path between the electrically connected or signal connected elements.

The term “power semiconductor device” refers to active semiconductor devices like diodes and transistors with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

According to an aspect of the disclosure, a method of manufacturing a semiconductor device may include forming a transfer foil that includes a porous silicon carbide layer. A composite substrate is formed that may include the transfer foil and a support substrate, wherein the transfer foil and the support substrate are brought into contact with each other and connected to each other. An epitaxial layer may be formed on a side of the porous silicon carbide layer opposite to the support substrate. The composite substrate is divided into a device substrate and a reclaim substrate, the device substrate including the epitaxial layer and the reclaim substrate including the support substrate.

The transfer foil may have two parallel foil surfaces and a uniform thickness given by a distance between the two foil surfaces. Hereinafter, two surfaces or planes may be seen as being “parallel” if the (e.g. imaginary) extensions of the two surfaces or planes enclose an angle of less than 5° or less than 3° or less than 1°.

The transfer foil may be a rigid film that may consist of the porous silicon carbide layer or may be a layer stack including at least one auxiliary layer in addition to the porous silicon carbide layer. The auxiliary layer(s) may include or consist of a material different from porous single crystalline silicon carbide. If the layer stack includes one single auxiliary layer, the auxiliary layer may include or consist of organic material or inorganic material. If the layer stack includes two or more auxiliary layers, all auxiliary layers may include or consist of organic material, all auxiliary layers may include or consist of inorganic material, or at least one of the auxiliary layers includes or consists of organic material and at least one of the other auxiliary layers includes or consists of inorganic material. For example, the auxiliary layer or at least one auxiliary layer is silicon-based and includes a silicon oxide and/or silicon nitride. The auxiliary layer or at least one auxiliary layer may be silicon carbide based. The auxiliary layer or at least one auxiliary layer may be carbon based. The auxiliary layer may include a glass, a ceramic, or a resin.

A lateral extent of the transfer foil may be sufficiently large to completely cover a planar main surface of a standard wafer. In particular, the transfer foil may be shaped such that the transfer foil covers a circle with a diameter of at least 4 inch, 150 mm, 200 mm or 300 mm. A shape of the transfer foil in a horizontal plane may be a circle or a polygon, e.g., a rectangle, a square or a hexagon.

The porous silicon carbide layer may have two parallel main surfaces. A thickness of the porous silicon carbide layer, which is given by a distance between the two main surfaces, may be uniform along the porous silicon carbide layer. It may also be possible that the thickness of the porous silicon carbide layer varies along the porous silicon carbide layer by up to 35% (or up to 10% or up to 5%) of a mean thickness of the porous silicon carbide layer. The thickness of the porous silicon carbide layer may be in a range from 1 nm to 50 μm.

The porous silicon carbide layer includes a single crystalline 3D support structure (“skeleton structure”) with closed and/or connected (e.g. communicating) pores. The main surfaces of the porous silicon carbide layer may be covered with functional groups such as Si—O—Si, Si—F₂ and/or C—Hₓ.

Defining a porosity of a layer as the proportion of the void volume (i.e., the “empty volume”) in the layer to the total volume of the layer, an average porosity of the porous silicon carbide layer is in a range from 10% to 80%, e.g., in a range from 30% to 60%. A local porosity determined with respect to a unit volume that is larger than a maximum pore size may vary from 1% to 80%.

In the porous silicon carbide layer, the local porosity may be homogenous. Alternatively, the porosity of the porous silicon carbide layer may be uniform only along directions parallel to the main surfaces and may change in a direction orthogonal to the main surfaces. For example, the porosity may gradually or in steps increase with increasing distance to one main surface or both main surfaces, or may decrease with increasing distance to both main surfaces. The porous silicon carbide layer may include vertically stacked partial layers of different porosity. For example, the porous silicon carbide layer may include a coarse-porous partial layer and a fine-porous partial layer, wherein the porosity of the coarse-porous partial layer is greater than the porosity of the fine-porous partial layer. For example, the course-porous partial layer may include large pores with a mean diameter greater than 50 nm, e.g., in a range from 50 nm to 200 nm, and high overall porosity of at least 30% and at most 80%, e.g., in a range from 40% to 60%. The fine-porous partial layer may include small pores with a mean diameter of at most 50 nm, e.g., smaller than 40 nm, and low overall porosity of at most 50%, e.g., in a range from 5% to 35%.

The porous silicon carbide layer may include a skin layer portion, wherein the skin layer portion contains pores at a porosity of less than 5% or is almost devoid of pores. The skin layer portion may directly adjoin one of the main surfaces of the porous silicon carbide layer.

The transfer foil may be obtained by forming a porous surface layer along a top surface of a source substrate from single crystalline silicon carbide and detaching the porous surface layer or a portion of the porous surface layer from the source substrate.

Forming the porous surface layer may include metal assisted photochemical etching (MAPCE). The metal assisted photochemical etching may use a noble metal layer as electrode.

Alternatively, the porous surface layer may be formed by electrochemical etching that induces anodic dissolution of the source substrate. For example, the source substrate may get into contact with an electrolyte containing fluorine, for example, hydrofluoric acid (HF), and a surface-active agent (surfactant). The surfactant may contain tetramethylammonium hydroxide (TMAH), potassium hydroxide (KOH), and/or ethanol. Alternatively, the electrolyte may be an aqueous HF solution. A cathode electrode may be immersed into the electrolyte and an electric potential may be applied between the cathode electrode and the source substrate, which forms the anode electrode. The electrochemical etching may be a dark process or may be a photoelectrochemical etching assisted by light.

The transfer foil including the porous silicon carbide layer may be detached from the source substrate by mechanical forces. For example, a stressor layer may be applied on a top surface of the porous surface layer and mechanical stress induced into the source substrate by the stressor layer may cause the porous silicon carbide layer to cleave along a horizontal plane. The stressor layer may be part of the transfer foil. The stressor layer may be removed before or after forming the composite substrate.

The transfer foil and the support substrate are brought into contact with each other and connected to each other, wherein a stable and permanent chemical bond may be formed between a first main surface (bonding surface) of the porous silicon carbide layer and a process surface of the support substrate. The support substrate consists of a support material different from the material of the source substrate or includes a top layer from a substrate material different from a base material of a source substrate from which the porous silicon carbide layer is obtained.

The process surface of the support substrate extends along two orthogonal horizontal (lateral) directions. A normal onto the process surface defines a vertical direction.

The substrate material and the source substrate may have the same main components silicon and carbon but different microstructures (German: Geftige). The support substrate may be a substrate other than a defect-free or nearly defect-free single crystalline silicon carbide substrate and may be cheaper than the source substrate from which the porous silicon carbide layer is obtained.

Connecting the transfer foil and the support substrate to each other forms a one-piece composite substrate.

The epitaxial layer may be formed directly on a second main surface (epitaxy surface) of the porous silicon carbide layer of the transfer foil. For example, the epitaxial layer may be formed directly on a skin layer portion of the porous silicon carbide layer. Forming the epitaxial layer includes a deposition process and, if applicable, a thermal treatment for re-crystallization of the deposited material to obtain the 4H-SiC. The deposition process may include chemical vapor deposition (CVD), metal organic chemical vapor deposition (MOCVD), organometallic vapor phase epitaxy (OMVPE) and/or molecular beam epitaxy (MBE). The epitaxial layer forms a silicon carbide single crystal, wherein the atoms of the single crystal continue the crystal lattice of the porous silicon carbide layer.

Dividing the composite substrate may include horizontally splitting the porous silicon carbide layer into two portions, e.g., horizontally cleaving the porous silicon carbide layer, wherein the composite substrate is separated into a device substrate and a reclaim substrate. The device substrate includes the epitaxial layer and may further include a device portion of the cleaved porous silicon carbide layer. The reclaim substrate includes the support substrate and may further include a reclaim portion of the cleaved porous silicon carbide layer.

The device substrate is separated in one piece from the reclaim substrate. The reclaim portion of the cleaved porous silicon carbide layer remains connected to the support substrate.

The reclaim portion of the cleaved porous silicon carbide layer may form a continuous layer or may include laterally separated islands. The device portion of the cleaved porous silicon carbide layer may form a continuous layer or may include laterally separated islands.

Dividing the composite substrate may include mechanically stressing the composite substrate in a way that splitting processes in the porous silicon carbide layer relieve the mechanical stresses before another portion of the composite substrate is mechanically damaged. The mechanical stress may act in a horizontal transversal direction, in a horizontal radial direction, in the vertical direction, and/or as torsional shear stress. Generating the mechanical stress may include generating temperature differences along the vertical direction, exploiting differences in thermal expansion coefficients between the composite substrate and at least one auxiliary structure firmly connected to one of the main surfaces of the composite substrate, twisting and/or pulling a chuck firmly connected to one of the main surfaces of the composite substrate and/or applying a leverage force to exfoliate the device substrate.

Alternatively or additionally, dividing the composite substrate may include selectively damaging the skeleton structure of the porous silicon carbide layer physically and/or chemically until the device substrate separates from the reclaim substrate or until the application of a comparatively weak mechanical force is sufficient to detach the device substrate from the composite substrate. For example, a horizontal fluid beam, a horizontal particle beam or horizontal radiation may be directed to an exposed lateral surface of the porous silicon carbide layer to remove material from the skeleton structure and weaken the skeleton structure of the porous silicon carbide layer. Alternatively or additionally, damaging the skeleton structure may include filling the pores with an auxiliary fill material and using the physical characteristics of the auxiliary fill material to damage the skeleton structure. Alternatively or additionally, damaging the skeleton structure may utilize the large surface of the pores for highly selective chemical decomposition or chemical conversion of the silicon carbide in the porous silicon carbide layer into volatile components and/or mechanically less stable compounds.

The epitaxial layer may be separated from the base portion along the porous structure after doped regions, insulator structures and/or conductive structures of electronic elements have been formed on and/or in the epitaxial layer. For example, the epitaxial layer may be separated from the base portion after forming semiconducting portions of semiconductor devices in the epitaxial layer. The separation process may include separating (e.g., cleaving) the porous structure along an approximately horizontal plane through a coarse-porous layered portion.

After removal of the reclaim portion of the cleaved porous silicon carbide layer, the reclaim substrate can be re-used as support substrate. The device substrate may be used for manufacturing semiconductor devices, wherein the device portion of the cleaved porous silicon carbide layer can be completely removed. Alternatively, the device portion of the cleaved porous silicon carbide layer can be smoothed and/or flattened, e.g. planarized.

The method decouples to a high degree epitaxy from porosification and enables a cost-efficient production of thin silicon carbide device substrates, such as those suitable for power semiconductor devices.

According to an embodiment, the support substrate may include a polycrystalline silicon carbide substrate, a single crystalline silicon carbide wafer of a polytype different from a polytype of the porous silicon carbide layer, or a single crystalline silicon carbide recycle substrate.

The polycrystalline silicon carbide substrate may be an unprocessed or nearly unprocessed polycrystalline silicon carbide wafer. The single crystalline silicon carbide substrate of a polytype different from the polytype of the porous silicon carbide layer may contain or consist of 2H-SiC, 3C-SiC, and/or 6H-SiC when the porous silicon carbide layer is formed of 4H-SiC.

The single crystalline silicon carbide recycle substrate may include single crystalline silicon carbide of any polytype but is not suitable for obtaining defect-free standard silicon carbide semiconductor devices at an economic scale. The recycle substrate may be a single crystalline 4H-SiC wafer that does not fulfill at least one of the relevant specifications set up for wafers for the manufacture of power semiconductor devices. For example, the single crystalline silicon carbide recycle wafer contains more impurity atoms and/or more crystal defects, has a resistivity outside a specified range or a surface orientation outside a specified range. The support substrate can be cheaper than the source substrate.

According to an embodiment, forming the composite substrate may include bonding the porous silicon carbide layer and the support substrate together. A permanent bond is formed between the porous silicon carbide layer and the support substrate.

The permanent bond can be a glueless bond or an adhesive bond, A glueless bond is formed by direct bonding or fusion bonding (German: Schmelzbonden). An adhesive bond is formed by applying an adhesive.

For example, the bonding surface of the porous silicon carbide layer may be directly bonded to the process surface of the support substrate. In this case, no adhesive material or no material other than material from the support substrate and the porous silicon carbide layer may be present along an interface between the porous silicon carbide layer and the support substrate. Direct bonding may be based on chemical bonds directly between two bonding members. For example, the two bonding members may be two of the following: (i) the support substrate, (ii) the porous silicon carbide layer, (iii) an (optional) non-adhesive bonding layer on the support substrate, (iv) an (optional) non-adhesive bonding layer on the porous silicon carbide layer. The non-adhesive bonding layer may comprise or consist of a semiconducting material and/or a metallic material.

Fusion bonding may include a pre-bonding at ambient temperature and an annealing at elevated temperatures. The pre-bonding brings the bonding surface of the porous silicon carbide layer into physical contact with the process surface of the support substrate. The annealing may activate and/or strengthen chemical bonds between the support substrate and the porous silicon carbide layer. Direct bonding (fusion bonding) may be assisted by applying a silicon carbide based liquid, a liquid silicon carbide precursor or amorphous silicon onto the processing surface of the support substrate and/or the bonding surface of the porous silicon carbide layer before the pre-bonding.

Alternatively, the porous silicon carbide layer of the transfer foil may be adhesive-bonded onto the process surface of the support substrate through an intermediate adhesion layer. The bonding is based on chemical bonds between the cured adhesion layer and the support substrate and chemical bonds between the cured adhesion layer and the porous silicon carbide layer.

Adhesive bonding may include applying a curable adhesive to the process surface of the support substrate and/or to the bonding surface of the porous silicon carbide layer, pressing the support substrate and the transfer foil against each other with the curable adhesive therebetween, and curing the adhesive, wherein the adhesive cures and forms the cured adhesive layer. The curable adhesive may be applied as a liquid, as a tape, or as a layer on a tape, by way of example.

In general, a surface pre-treatment or surface conditioning may be performed before bonding. For example, such a pre-treatment or conditioning may include a treatment with a plasma and/or a wet chemistry solution.

According to an embodiment, the porous silicon carbide layer may include a bonding surface with a C-face and forming the composite substrate includes bonding the bonding surface of the porous silicon carbide layer to the support substrate.

The C-face bonding surface may simplify direct bonding of the transfer foil to a Si-face of a single-crystalline recycle substrate of the same polytype as the porous silicon carbide layer. Bonding the C-face of the porous silicon carbide layer to the support substrate may leave the Si-face of the porous silicon carbide layer accessible for further processing.

According to an embodiment, the porous silicon carbide layer may include an epitaxy surface with a Si-face and the epitaxial layer is formed on the epitaxy surface of the porous silicon carbide layer.

The porous silicon carbide layer may be formed with a significant lower porosity along a surface having the Si-face than along a surface having the C-face.

Growing an epitaxial layer on an epitaxy surface with a Si-face can be less complicated than growing an epitaxial layer on a C-face.

According to an embodiment, an electronic element may be formed in and/or on the epitaxial layer before dividing the composite substrate.

The electronic element may be an active semiconductor element. For example, the electronic element is a semiconductor diode or a transistor. Doped semiconductor regions of the electronic element such as an anode region of a semiconductor diode or the source/emitter region of a transistor can be formed in the epitaxial layer. An anode electrode of a semiconductor diode or the source/emitter electrode and of a transistor can be formed on the epitaxial layer. A gate electrode of a transistor can be formed on the epitaxial layer or in trenches extending from a front side into the epitaxial layer.

According to an embodiment, the method may include a backside processing of an exposed back surface of the device substrate.

Dividing the composite substrate includes cleaving the porous silicon carbide layer, wherein the back surface of the device substrate is separated from a front side surface of the reclaim substrate. The exposed back surface is formed by the device portion of the cleaved porous silicon carbide layer.

The backside processing may include a CMP that planarizes and/or recesses the device portion of the cleaved porous silicon carbide layer, wherein the device portion of the cleaved porous silicon carbide layer may be completely removed from the device substrate, or wherein a planarized device portion of the cleaved porous silicon carbide layer forms a porous backside layer of the device substrate. Alternatively or in addition, the backside processing may include introducing dopants through the exposed back surface, a selective thermal treatment, and/or deposition of material, e.g., deposition of a metal layer.

According to an embodiment, a metal layer may be formed on an exposed back surface of the device substrate.

The metal layer may be a homogenous layer of may be a layer stack including two or more vertically stacked sublayers of different composition and/or structure.

According to an embodiment, an ohmic contact may be formed on a back side of the device substrate.

Forming the ohmic contact may include introducing impurities through the exposed back surface of the device substrate to form a heavily doped contact layer along the back surface and forming a metal layer on the heavily doped contact layer, wherein the metal layer and the heavily doped contact layer form an ohmic contact. Introducing the impurities may include implanting dopants through the back surface of the device substrate. Forming the ohmic contact may include a local heat treatment of the back surface, e.g., a laser thermal anneal (LTA).

The metal layer may form an electrode of a vertical semiconductor device with a current flow between the front side and the back side in a forward mode of a semiconductor diode or in an on-state of a power transistor.

According to an embodiment, forming the transfer foil may include forming a porous surface layer at a front side of a single crystalline silicon carbide source substrate and separating a foil portion of the porous surface layer from the source substrate, wherein the foil portion forms the porous silicon carbide layer of the transfer foil.

The source substrate has a planar first main surface that extends along two orthogonal horizontal (lateral) directions. A normal onto the first main surface defines a vertical direction.

The foil portion is removed in one piece from the rest of the source substrate. A substrate portion of the porous surface layer may remain connected to the non-porosified, non-porous substrate portion of the source substrate. The substrate portion may form a continuous layer or may include laterally separated islands.

Separating the foil portion from the porous surface layer horizontally splits the porous surface layer into two portions and may include mechanically stressing the source substrate in a way that splitting processes in the porous surface layer relieve the mechanical stresses before another portion of the source substrate is mechanically damaged. The mechanical stress may act in a horizontal transversal direction, in a horizontal radial direction, in the vertical direction, or as torsional shear stress. Generating the mechanical stress may include generating temperature differences along the vertical direction, exploiting differences in thermal expansion coefficients between the source substrate and at least one auxiliary structure firmly connected to one of the main surfaces of the source substrate, twisting and/or pulling a chuck firmly connected to one of the main surfaces of the source substrate and/or applying a leverage force to exfoliate the foil portion.

Alternatively or additionally, separating the foil portion of the porous surface layer from the source substrate may include selectively damaging the skeleton structure of the porous surface layer physically and/or chemically until the foil portion of the porous surface layer detaches from a substrate portion or until the application of a comparatively weak mechanical force is sufficient to detach the foil portion from the source substrate. For example, a horizontal fluid beam, a horizontal particle beam or horizontal radiation may be directed to an exposed lateral surface of the porous surface layer to remove material from the skeleton structure and weaken the skeleton structure of the porous surface layer. Alternatively or additionally, damaging the skeleton structure may include filling the pores with an auxiliary fill material and using the physical characteristics of the auxiliary fill material to damage the skeleton structure. Alternatively or additionally, damaging the skeleton structure may utilize the large surface of the pores for highly selective chemical decomposition or chemical conversion of the silicon carbide in the porous surface layer into volatile components and/or mechanically less stable compounds.

The transfer foil may include an auxiliary layer applied to one of the main surfaces of the porous silicon carbide layer. For example, the auxiliary layer may be formed or applied on the porous surface layer before dividing the porous surface layer. Alternatively, or in addition, an auxiliary layer may be applied to at least one of the main surfaces of the porous silicon carbide layer after separating the foil portion from the source substrate.

A reclaim portion of the source substrate including the substrate portion of the porous surface layer and the non-porous substrate portion of the source substrate can be reworked. For example, the substrate portion of the porous surface layer may be planarized or completely removed such that in a next cycle a further porous surface layer can be formed in the reworked reclaim portion of the source substrate.

According to an embodiment, forming the porous surface layer may include metal assisted photochemical etching (MAPCE).

MAPCE may form the porous silicon carbide layer on the C-face of the source substrate.

According to an embodiment, dividing the composite substrate may include generating horizontal mechanical stress in the porous silicon carbide layer.

Horizontal mechanical stress may be generated by radial, transverse and/or by torsional forces. The mechanical stress may generate and/or promote growth of horizontal cracks in vertical columns of the skeleton structure in the porous silicon carbide layer until the composite substrate is separated into two parts.

Generating horizontal mechanical stress may include forming or firmly attaching, e.g. bonding, a stressor layer on a main surface of the composite substrate and exposing the composite substrate to a thermal treatment, wherein different degrees of thermal expansion in the composite substrate and the stressor layer generate radial mechanical stress in the composite substrate. The mechanical stress may have a maximum in a horizontal layer part with the highest porosity.

According to another aspect of the disclosure, a composite substrate may include a support substrate that includes single crystalline silicon carbide. A single crystalline porous silicon carbide layer is on a process surface of the support substrate, wherein a polytype of the support substrate is different from a polytype of the porous silicon carbide layer and/or the support substrate is a recycle wafer. An epitaxial layer is formed on a side of the porous silicon carbide layer opposite to the support substrate.

The support substrate may include a non-porous single crystalline silicon carbide layer or may consist of non-porous single crystalline silicon carbide.

According to an embodiment the single crystalline porous silicon carbide layer may be in direct contact with the process surface of the support substrate. For example, the single crystalline porous silicon carbide layer is directly bonded to a non-porous single crystalline silicon carbide layer of the support substrate or to a support substrate consisting of non-porous single crystalline silicon carbide. Chemical bonds, e.g. silicon-to-carbon bonds, are formed between the single crystalline porous silicon carbide layer and the support substrate.

According to an embodiment the epitaxial layer may be in direct contact with the porous silicon carbide layer. For example, the porous silicon carbide layer may include a low-porosity skin layer portion with a porosity of less than 5% and a thickness of at most 300 nm. The epitaxial layer may be in direct contact with the low-porosity skin layer portion.

According to another aspect of the disclosure, a power semiconductor device may include a single crystalline porous silicon carbide portion having laterally homogenous porosity. A non-porous silicon carbide portion is in direct contact with a main surface of the porous silicon carbide portion. An active semiconductor element includes semiconducting regions formed in the non-porous silicon carbide portion. A first load electrode is formed at a front side of the non-porous silicon carbide portion opposite to the porous silicon carbide portion. A second load electrode is formed at a rear side of the porous silicon carbide portion opposite to the main surface of the porous silicon carbide portion.

According to an embodiment, the single crystalline porous silicon carbide portion may have a laterally constant dopant concentration gradient.

In the skeleton structure of the porous silicon carbide portion, the dopant concentration does not change along the lateral directions.

A doping level in the porous silicon carbide portion and a doping level in the non-porous silicon carbide portion may be the same or at least similar, wherein the doping level in the porous silicon carbide portion falls below or exceeds the doping level in the non-porous silicon carbide portion by at most 50% of the doping level in the non-porous silicon carbide portion. Alternatively, the doping level in the porous silicon carbide portion falls below or exceeds the doping level in the non-porous silicon carbide portion by more than 50% of the doping level in the non-porous silicon carbide portion.

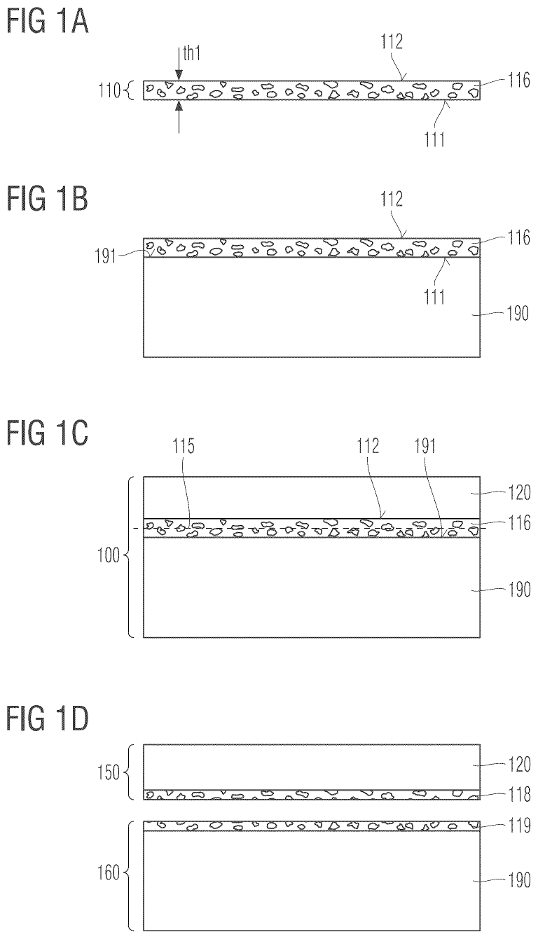

FIG. 1A to FIG. 1D concern an embodiment with a transfer foil 110 including not more than a porous silicon carbide layer 116 as illustrated in FIG. 1A.

The porous silicon carbide layer 116 has two parallel main surfaces 111, 112. The main surfaces 111, 112 are planar or at least approximately planar and have a lateral extension along two orthogonal horizontal directions. A first main surface 111 at a first side of the porous silicon carbide layer 116 may have a carbon face (C-face). A second main surface 112 at the second side of the porous silicon carbide layer 116 may have a silicon face (Si-face).

The lateral extension may be sufficiently large to cover completely a front side of a standard wafer with a diameter of at least 4 inch, 150 mm, 200 mm or 300 mm. A horizontal shape of the porous silicon carbide layer 116 may be rectangular or circular, by way of example. A distance between the first main surface 111 and the second main surface 112 corresponds to a thickness th1 along a vertical direction orthogonal to the horizontal directions. The thickness th1 of the porous silicon carbide layer 116 may be in a range from 5 nm to 100 μm, e.g., 10 μm to 30 μm.

The porous silicon carbide layer 116 includes closed and/or connected pores embedded in a single crystalline, massive supporting structure (skeleton structure). The single crystalline supporting structure has the 4H polytype. A dopant concentration in the single crystalline supporting structure is uniform in the horizontal directions and may be uniform or may show a stepless or stepped variation along the vertical direction.

A porosity of the porous silicon carbide layer is constant in the horizontal directions. In the vertical direction, the porosity of the porous silicon carbide layer is constant or has a stepless or stepped variation. An average porosity of the porous silicon carbide layer is in a range from 10% to 80%, e.g., in a range from 30% to 60%. Along the second main surface 112, the porosity may be less than 5%, e.g., less than 1%. Along the first main surface 111, the porosity may be higher than along the second main surface 112, e.g., higher than 50%.

The first main surface 111 and/or the second main surface 112 of the porous silicon carbide layer may be covered with functional groups such as Si—O—Si, Si—F₂ and/or C—Hₓ.

The porous silicon carbide layer 116 is brought into contact with a planar process surface 191 of a support substrate 190. A stable and permanent chemical bond is formed between the porous silicon carbide layer 116 and the support substrate 190.

The support substrate 190 includes or consists of a non-porous substrate material, wherein a thermal expansion coefficient of the substrate material and a thermal expansion coefficient of the porous silicon carbide layer 116 may be equal or deviate from each other by not more than 5% from the average value of the two thermal expansion coefficients.

The lateral extension of the support substrate 190 may comply with a standard wafer with a diameter of at least 4 inch, 150 mm, 200 mm or 300 mm.

The material of the support substrate 190 is different from a non-porous single crystalline silicon carbide substrate having the polytype of the porous silicon carbide layer 116 and meeting the specifications for a source substrate for the manufacture of power semiconductor devices in terms of resistivity, crystal orientation, crystal defect density, dopant concentration, hydrogen content, and/or oxygen content, by way of example. For example, the substrate material of the support substrate 190 may be single crystalline 3C-SiC, 2H-SiC or 6H-SiC or polycrystalline silicon carbide. Alternatively, the support substrate is a recycle wafer that does not fulfill the specifications for an initial substrate for the manufacture of power semiconductor devices.

Connecting the porous silicon carbide layer 116 and the support substrate 190 may include direct bonding or fusion bonding with or without applying liquid silicon carbide onto the process surface 191 of the support substrate 190 and/or the first main surface 111 (bonding surface) of the porous silicon carbide layer 116 before bringing the bonding surface 111 of the porous silicon carbide layer 116 and the process surface 191 of the support substrate 190 in contact with each other.

FIG. 1B shows a one-piece composite substrate 100 that includes the porous silicon carbide layer 116 and the support substrate 190.

An epitaxial layer 120 is formed directly on the second main surface 112 (epitaxy surface) of the porous silicon carbide layer 116. Forming the epitaxial layer 120 includes a deposition process and, if applicable, a thermal treatment for re-crystallization of the deposited material to obtain the 4H-SiC. The deposition process may include chemical vapor deposition (CVD), metal organic chemical vapor deposition (MOCVD), organometallic vapor phase epitaxy (OMVPE) and/or molecular beam epitaxy (MBE). The epitaxial layer 120 grows in registry with the crystal lattice of the porous silicon carbide layer 116. An initial phase of the epitaxy may be controlled to facilitate some lateral overgrowth across gaps in the epitaxy surface 112 of the porous silicon carbide layer 116.

In FIG. 1C, the one-piece composite substrate 100 includes the support substrate 190, the porous silicon carbide layer 116 and the epitaxial layer 120 grown on the epitaxy surface 112 of the porous silicon carbide layer 116. The epitaxial layer 120 forms a single crystal, wherein the atoms of the single crystal continue the crystal lattice of the porous silicon carbide layer 116. The porous silicon carbide layer 116 may include a low-porous skin layer along the epitaxy surface 112, wherein the skin layer forms before the epitaxy and/or in an initial phase of the epitaxy.

One or more active electric elements can be formed in and/or on the epitaxial layer 120. Then the porous silicon carbide layer 116 is cleaved in an approximately horizontal cleavage portion 115. The cleavage portion 115 may include a coarse-porous layered portion of the porous silicon carbide layer 116. In particular, the cleavage portion 115 may include a vertical high porosity sub-layer of the porous silicon carbide layer 116, wherein in the high porosity sub-layer the porosity of the porous silicon carbide layer 116 has a maximum. A vertical extension of the cleavage portion 115 may be small in relation to the thickness th1 of the porous silicon carbide layer 116. The cleavage portion 115 may be at a distance to both the epitaxial layer 120 and the support substrate 190 or may directly adjoin the support substrate 190.

Cleaving the porous silicon carbide layer 116 may include attaching a stressor substrate having a coefficient of thermal expansion different from the coefficient of thermal expansion of the composite substrate 100 to at least one of the main surfaces of the composite substrate 100, and then cooling or heating the composite including the stressor substrate and the composite substrate 100 to generate thermomechanical stress in the porous silicon carbide layer 116 along a horizontal radial direction.

Alternatively, thermomechanical stress may be induced into the porous silicon carbide layer 116 by generating a vertical temperature gradient in the composite substrate 100. Any type of cleaving process as discussed above can be used.

As shown in FIG. 1D, the composite substrate 100 of FIG. 1C is separated into a device substrate 150 and a reclaim substrate 160. The device substrate 150 includes the epitaxial layer 120 and a device portion 118 of the porous silicon carbide layer 116. The reclaim substrate 160 includes a reclaim portion 119 of the porous silicon carbide layer 116 and the support substrate 190.

The device substrate 150 can be further processed. For example, the device portion 118 of the porous silicon carbide layer 116 may be removed from the device substrate 150. A removal of the device portion 118 may include a mechanical, chemical, physical polishing, or a combination of different polishing methods like chemical mechanical polishing (CMP). The CMP may expose a back surface of the epitaxial layer 120. A metal layer may be deposited on the back surface of the epitaxial layer 120. From the device substrate 150 semiconductor dies of power semiconductor devices are obtained by dicing.

The reclaim portion 119 of the cleaved porous silicon carbide layer 116 is removed from the reclaim substrate 160. Then the reclaim substrate 160 can be re-used as another support substrate 190, and the process of transferring a porous silicon carbide layer 116 to a support substrate, growing an epitaxial layer on the porous silicon carbide layer 116 and splitting off a device substrate from the composite substrate obtained can be repeated.

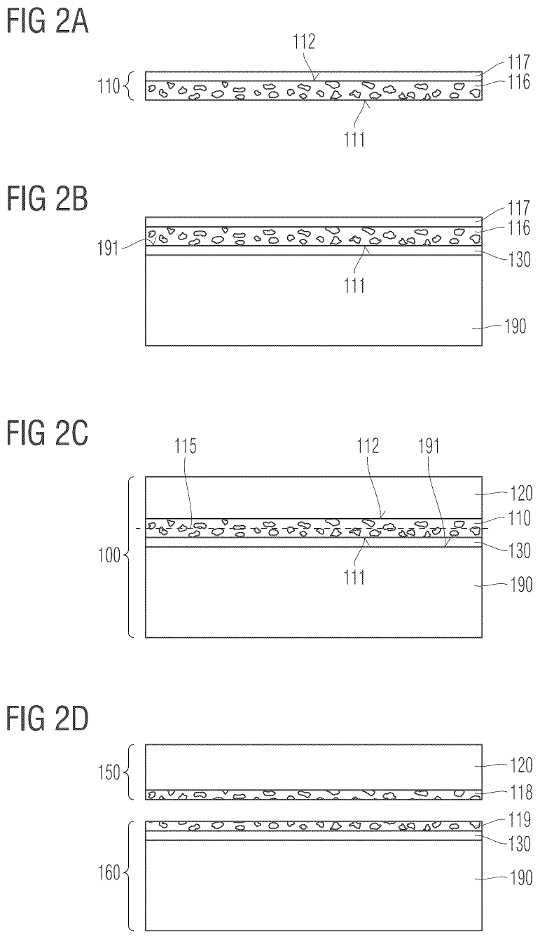

In FIG. 2A to FIG. 2D, the transfer foil 110 includes an auxiliary layer 117 formed on or attached to the epitaxy surface 112 of the porous silicon carbide layer 116 as illustrated in FIG. 2A.

The auxiliary layer 117 may be a homogenous layer or layer stack including at least two vertically stacked layers of different composition and/or microstructure. The auxiliary layer 117 may include an adhesive tape and/or a rigid support layer.

An interface layer 130 may be formed on the process surface 191 of the support substrate 190. The interface layer 130 includes a layer containing silicon. For example, the interface layer 130 includes or consists of a silicon nitride.

The porous silicon carbide layer 116 is brought into contact with a planar process surface 131 of the interface layer 130. A stable and permanent chemical bond is formed between the porous silicon carbide layer 116 and the interface layer 130. The auxiliary layer 117 is removed.

FIG. 2B shows the porous silicon carbide layer 116 with the bonding surface 111 directly bonded to the interface layer 130. In the absence of the interface layer 130, the porous silicon carbide layer 116 is directly bonded to the support substrate 190.

FIG. 2C and FIG. 2D show the growth of an epitaxial layer 120 on the epitaxy surface 112 of the porous silicon carbide layer 116 and the splitting of the composite substrate 100 along a cleavage portion 115 of the porous silicon carbide layer 116 as described above with reference to FIG. 1C and FIG. 1D with the difference of the interface layer 130 formed between the porous silicon carbide layer 116 and the support substrate 190.

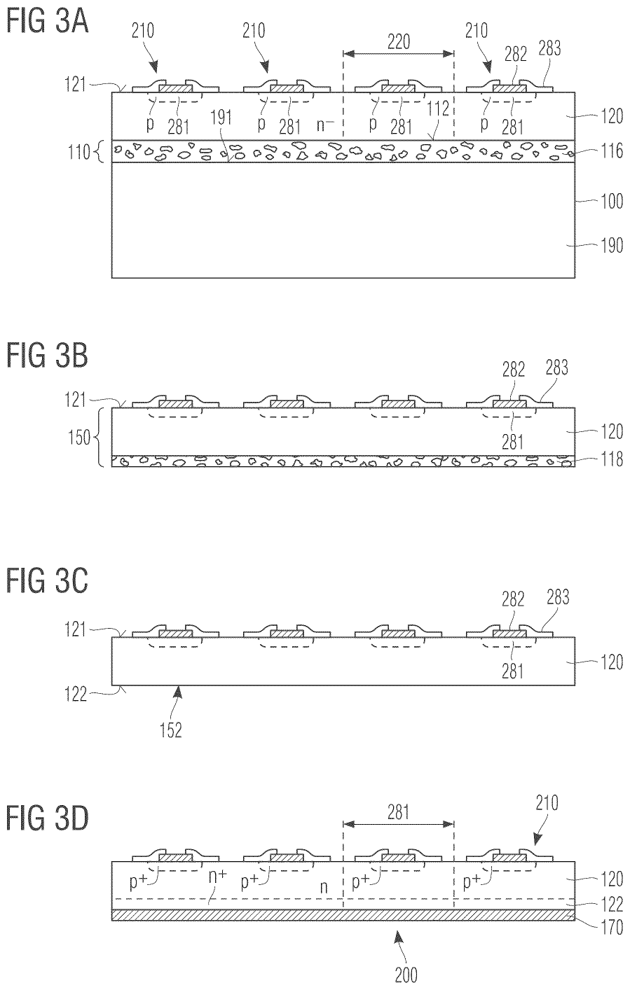

FIG. 3A to FIG. 3D illustrate a method that obtains semiconductor dies 200 from a device substrate 150 that has been cleaved off from a composite substrate 100 using a porous silicon carbide layer 116 applied through a transfer foil 110.

A composite substrate 100 is formed by bonding a transfer foil 110 including a porous silicon carbide layer 116 onto a process surface 191 of a support substrate 190 and growing by epitaxy a low n doped epitaxial layer 120 on an epitaxy surface 112 of the porous silicon carbide layer 116.

Semiconducting regions, conductive structures, and insulating structures of electronic elements 210 are formed in and/or on the epitaxial layer 120.

As shown in FIG. 3A, the epitaxial layer 120 includes a plurality of equal-sized device regions 220 arranged along two orthogonal horizontal directions. In each device region 220 the same type of electronic element 210 is formed.

In the illustrated embodiment, acceptor atoms are implanted through a main surface 121 at a front side of the epitaxial layer 120 opposite to the porous silicon carbide layer 116 to form a p doped anode region 281 in each device region 220. Depositing and patterning a metal layer or metal layer stack form an anode electrode 282 in each device region 220, wherein the anode electrode 282 and the anode region 281 form an ohmic contact. Depositing and patterning an insulator layer or insulator layer stack form a passivation structure 283 covering inter alia a sidewall of the anode electrode 282 in each device region 220.

The composite substrate 100 is divided into a device substrate 150 and a reclaim substrate as described with reference to FIG. 1D.

FIG. 3B shows the device substrate 150 including the epitaxial layer 120 and the device portion 118 of the porous silicon carbide layer.

A polishing process removes the device portion 118 of the porous silicon carbide layer and exposes the epitaxial layer 120 at the rear side of the device substrate 150.

As illustrated in FIG. 3C, the back surface 152 of the device substrate 150 exposes the epitaxial layer 120.

Donor atoms may be introduced, e.g., implanted through the back surface 152 of the device substrate 150. One or more metal containing layers are deposited on the back surface 152 of the device substrate 150. Before or after depositing the one or more metal containing layers, a local heat treatment activates the introduced donor atoms.

The activated donor atoms form a heavily doped contact layer 122 along the back surface 152 of the device substrate 150. The one or more deposited metal containing layers form a metal layer structure 170. The heavily doped contact layer 122 and the metal layer structure 170 form an ohmic contact.

A dicing process laterally separates the device regions 220 of the device substrate 150 from each other, wherein each separated device region 220 forms the semiconductor die 200 of a vertical power semiconductor diode with a cathode electrode formed from a portion of the metal layer structure 170. A forward current of the power semiconductor diode flows between the anode electrode 282 at the front side and the cathode electrode at the backside of the semiconductor die 200.

Instead of power semiconductor diodes, vertical transistors, for example, MOSFETs or IGBTs can be formed in the semiconductor dies 200. Instead of completely removing the device portion 118 of the porous silicon carbide layer 116 and forming the metal layer structure 170 on a surface of the epitaxial layer 120, CMP may remove only a part of the device portion 118 of the porous silicon carbide layer 116 and the metal layer structure 170 is formed on a recessed and planarized surface of the device portion 118 of the porous silicon carbide layer 116.

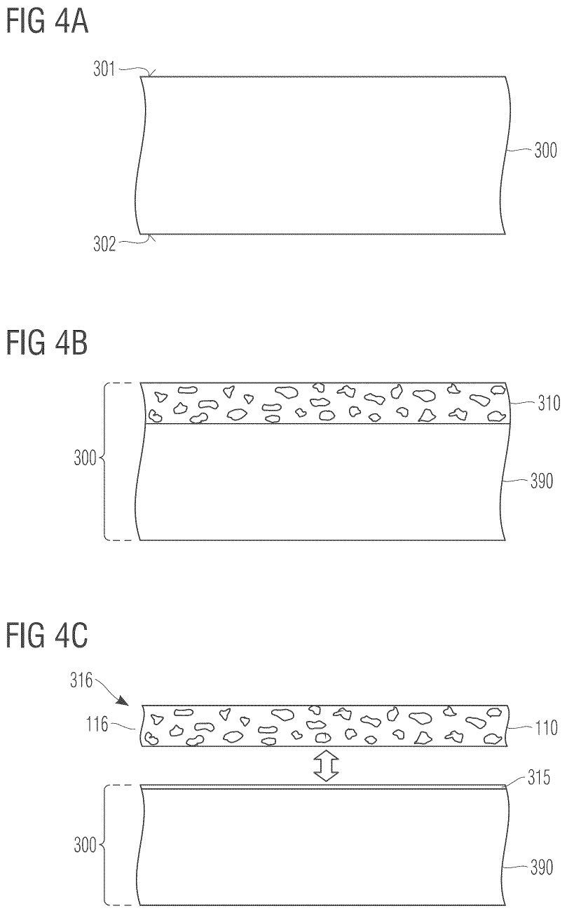

FIG. 4A to FIG. 4C illustrate a process of forming a transfer foil 110 that includes a single-crystalline, porous silicon carbide layer 116.

FIG. 4A shows a non-porous single crystalline silicon carbide source substrate 300. The source substrate 300 is a single crystalline wafer or boule and has two parallel main surfaces 301, 302. The polytype of the silicon carbide is 4H. A first main surface 301 may have an off-axis cut of about 4 degrees against the [0001] main crystal plane. The first main surface 301 at the front side of the source substrate 300 has a C-face.

A porous surface layer 310 is formed on the first main surface 301 of the source substrate 300 by MAPCE. MAPCE porosifies (makes porous) a surface layer of the source substrate 300 below the first surface 301.

FIG. 4B shows the porous surface layer 310 formed by MAPCE and the non-porous substrate portion 390 of the source substrate 300. The porous surface layer 310 is formed in a section of the source substrate 300 directly below the first main surface 301.

FIG. 4C shows a separation process that divides the porous surface layer 310 into a foil portion 316 and a substrate portion 315. The foil portion 316 includes a first layer portion of the porous surface layer 310 and forms the porous silicon carbide layer 116 of a transfer foil 110. The substrate portion 315 includes a second layer portion of the porous surface layer 316. The substrate portion 315 of the porous surface layer 310 and the non-porous substrate portion 390 form a reclaim portion 360 of the source substrate 300.

Before or after separating the foil portion 316 and the substrate portion 315, an auxiliary layer may be formed on or attached to a front side of the foil portion 316, so that the transfer foil 110 includes the porous silicon carbide layer 116 and the auxiliary layer.

The reclaim portion of the source substrate including the substrate portion of the divided porous surface layer and the non-porous substrate portion of the source substrate is reworked. For example, the substrate portion of the porous surface layer is planarized or completely removed such that in a next cycle a further porous surface layer can be formed in the reworked reclaim portion of the source substrate.

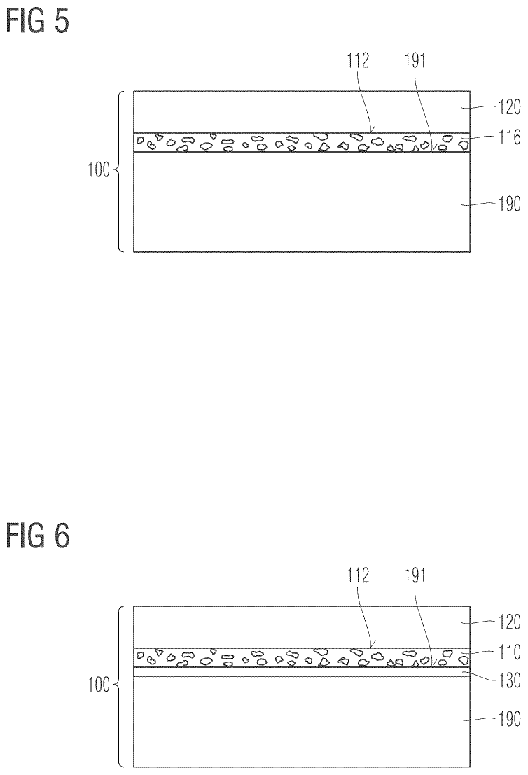

FIG. 5 and FIG. 6 show composite substrates 100 including a support substrate 190 that includes single crystalline silicon carbide. A single crystalline porous silicon carbide layer 116 of the 4H polytype is present on a process surface 191 of the support substrate 190. The support substrate 190 is a recycle wafer or has a polytype different from 4H.

An epitaxial layer 120 is formed on an epitaxy surface 112 of the porous silicon carbide layer 116 opposite to the support substrate 190. The epitaxial layer 120 is in direct contact with the porous silicon carbide layer 116. The porous silicon carbide layer 116 includes a low-porosity skin layer portion with a porosity of less than 5%. The epitaxial layer 120 is in direct contact with the low-porosity skin layer portion.

In FIG. 5 the single crystalline porous silicon carbide layer 116 is in direct contact with the process surface 191 of the support substrate 190. Silicon-to-carbon bonds are formed between the single crystalline porous silicon carbide layer 116 and the support substrate 190.

In FIG. 6 the single crystalline porous silicon carbide layer 116 is in direct contact with an interface layer 130 formed on the process surface 191 of the support substrate 190. Chemical bonds are formed between the single crystalline porous silicon carbide layer 116 and the interface layer 130. Chemical bonds are also formed between the interface layer 130 and the support substrate 190. The interface layer 130 may include nitrogen atoms.

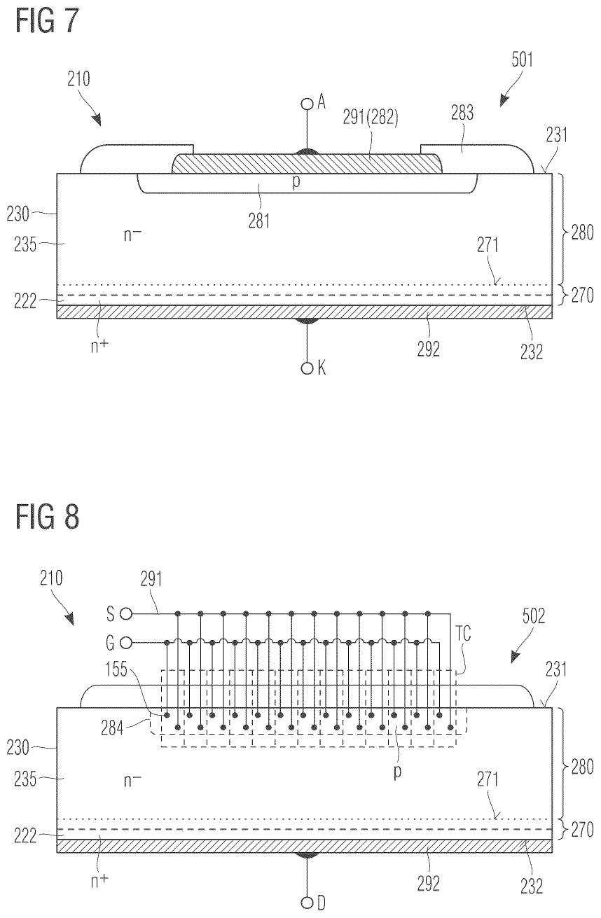

FIG. 7 and FIG. 8 show semiconductor dies 200 of power semiconductor devices 501, 502 obtainable from the composite substrate of FIG. 6.

The semiconductor die 200 includes a single crystalline silicon carbide body 230 with a planar front surface 231 at a front side and an opposite planar back surface 232. The front surface 231 and the back surface 232 are parallel to each other and extend horizontally. A distance between the front surface 231 and the back surface 232 defines a thickness of the silicon carbide body. A vertical direction is defined orthogonal to the horizontal directions.

The silicon carbide body 230 includes a single crystalline porous silicon carbide portion 270 and a non-porous silicon carbide portion 280 between the porous silicon carbide portion 270 and the front surface 231. The non-porous silicon carbide portion 280 is in direct contact with a planar horizontal main surface 271 of the porous silicon carbide portion 270.

A first load electrode 291 is formed at a front side of the non-porous silicon carbide portion 280 opposite to the porous silicon carbide portion 270. A second load electrode 292 is formed at a rear side of the porous silicon carbide portion 270 opposite to the main surface 271 of the porous silicon carbide portion 270. The first and second load electrode 291 include one or more metal layers. An insulating passivation structure 283 covers a portion of the front side surface 231 next to the first load electrode 291, a portion of the first load electrode 291, and a sidewall of the first load electrode 291.

The semiconductor body 230 includes a heavily doped contact portion 222 formed along the back surface 232 of the semiconductor body 230 and a weakly doped drift region between a front surface 231 and the contact portion 222. The contact portion 222 is obtained from a contact layer 122 of a device substrate 150 as illustrated in FIG. 3D. In the illustrated embodiments, the contact portion 222 is completely formed in the porous silicon carbide portion 270. The contact portion 222 and the second load electrode 292 form an ohmic contact.

FIG. 7 shows a power semiconductor diode 501 with the first load electrode 291 forming an anode electrode 282 and the second load electrode 292 forming a cathode electrode. The anode electrode 282 forms or is connected to an anode terminal A. The cathode electrode forms or is connected to a cathode terminal K. The contact portion 222 is heavily n doped. A p doped anode region 281 is formed along the front surface 231 of the semiconductor body 230. The anode region 281 and the anode electrode 282 form an ohmic contact. The anode region 281 and the drift region 235 form a pn junction.

FIG. 8 shows a power transistor 502 with the first load electrode 291 forming a source electrode and the second load electrode 292 forming a drain electrode. The source electrode forms or is connected to a source terminal S. The drain electrode forms or is connected to a drain terminal D. The contact portion 222 is heavily n doped. A transistor control region 284 is formed along a front surface 231 of the semiconductor body 230. The transistor control region 284 includes n doped source regions of transistor cells TC and one or more p doped wells separating the source regions and the n doped drift region 235. The source electrode forms ohmic contacts with the source regions and the p doped well.

The porosity of the porous silicon carbide portion 270 does not change along the lateral directions. The porosity is constant along the lateral directions. The porosity decreases along the vertical direction with increasing distance to the back surface 232 of the silicon carbide body 230.

A dopant concentration in the porous silicon carbide portion 270 does not change along the lateral directions. The dopant concentration is constant along the lateral directions.

What is claimed is:

1. A method of manufacturing a semiconductor device, the method comprising:
forming a transfer foil comprising a porous silicon carbide layer;
forming a composite substrate comprising the transfer foil and a support substrate, wherein the transfer foil and the support substrate are brought into contact to each other and connected to each other;
forming an epitaxial layer on a side of the porous silicon carbide layer opposite to the support substrate; and
dividing the composite substrate into a device substrate and a reclaim substrate, the device substrate comprising the epitaxial layer and the reclaim substrate comprising the support substrate.

2. The method of claim 1,
wherein the support substrate comprises a polycrystalline silicon carbide substrate, a substrate including single crystalline silicon carbide of a polytype different from a polytype of the porous silicon carbide layer, and/or a silicon carbide recycle substrate.

3. The method of claim 1,
wherein forming the composite substrate comprises bonding the transfer foil to the support substrate.

4. The method of claim 1,
wherein the porous silicon carbide layer comprises a bonding surface with a C-face, and
wherein forming the composite substrate comprises bonding the bonding surface of the porous silicon carbide layer to the support substrate.

5. The method of claim 1,
wherein the porous silicon carbide layer comprises an epitaxy surface with a Si-face, and
wherein the epitaxial layer is formed on the epitaxy surface of the porous silicon carbide layer.

6. The method of claim 1, further comprising:
before dividing the composite substrate, forming semiconducting regions of an electronic element in and/or on the epitaxial layer.

7. The method of claim 1, further comprising:
processing an exposed back surface of the device substrate.

8. The method of claim 1, further comprising:
forming a metal layer structure on an exposed back surface of the device substrate.

9. The method of claim 1, further comprising:
forming an ohmic contact on a back side of the device substrate.

10. The method of claim 1,
wherein forming the transfer foil comprises forming a porous surface layer at a front side of a single crystalline silicon carbide source substrate and separating a foil portion of the porous surface layer from the source substrate, and
wherein the foil portion forms the porous silicon carbide layer of the transfer foil.

11. The method of claim 10,
wherein forming the porous surface layer comprises metal assisted photochemical etching.

12. The method of claim 1,
wherein dividing the composite substrate comprises inducing horizontal mechanical stress in the porous silicon carbide layer.

13. A composite substrate, comprising:
a support substrate comprising single crystalline silicon carbide;
a single crystalline porous silicon carbide layer on a process surface of the support substrate, wherein a polytype of the support substrate is different from a polytype of the porous silicon carbide layer and/or the support substrate is a recycle wafer; and
an epitaxial layer formed on a side of the porous silicon carbide layer opposite to the support substrate.

14. The composite substrate of claim 13,
wherein the single crystalline porous silicon carbide layer is in direct contact with the process surface of the support substrate.

15. The composite substrate of claim 13,
wherein the epitaxial layer is in direct contact with the porous silicon carbide layer.

16. A power semiconductor device, comprising:
a single crystalline porous silicon carbide portion having laterally homogenous porosity;
a non-porous silicon carbide portion in direct contact with a main surface of the porous silicon carbide portion;
an active electronic element comprising semiconducting regions formed in the non-porous silicon carbide portion;
a first load electrode formed at a front side of the non-porous silicon carbide portion opposite to the porous silicon carbide portion; and
a second load electrode formed at a rear side of the porous silicon carbide portion opposite to the main surface of the porous silicon carbide portion.

17. The power semiconductor device of claim 16,
wherein the single crystalline porous silicon carbide portion has a laterally constant dopant concentration gradient.
